(19) United States
(12) Patent Application Publication
(10) Pub. No.: US 2025/0192127 A1
(43) Pub. Date: Jun. 12, 2025

(54) SEMICONDUCTOR PACKAGE INCLUDING BRIDGE STRUCTURE

(71) Applicant: SAMSUNG ELECTRONICS CO., LTD.

(72) Inventor: Dong Joo CHOI, Suwon-si (KR)

(73) Assignee: SAMSUNG ELECTRONICS CO., LTD., (omitted)

(21) Appl. No.: 18/947,592

(22) Filed: Nov. 14, 2024

(30) Foreign Application Priority Data
Dec. 6, 2023 (KR) 10-2023-0175495

(51) Int. Cl. H01L 25/18; H01L 23/00; H01L 23/48; H01L 23/538; H10B 80/00

(52) U.S. Cl. CPC H01L 25/18; H01L 23/5383; H01L 24/08; H01L 24/16; H01L 23/481; H01L 2224/08146; H01L 2224/08225; H01L 2224/16146; H10B 80/00

(57) ABSTRACT

Disclosed is a semiconductor package comprising a connection substrate, a first processor chip on the connection substrate, a second processor chip on the connection substrate, a memory chip stack structure on the first processor chip, and a bridge structure on the first processor chip and the second processor chip. The bridge structure electrically connects the first processor chip and the second processor chip. The first processor chip includes a first through via that overlaps the memory chip stack structure.

### CROSS-REFERENCE TO RELATED APPLICATION

This application claims priority under 35 U.S.C § 119 to Korean Patent Application No. 10-2023-0175495 filed on Dec. 6, 2023 in the Korean Intellectual Property Office, the disclosure of which is hereby incorporated by reference in its entirety.

### BACKGROUND

The present disclosure relate to a semiconductor package, and more particularly, to a semiconductor package including a bridge structure.

A semiconductor package is provided to implement an integrated circuit chip to qualify for use in electronic products. Typically, a semiconductor package is configured such that a semiconductor chip is mounted on a printed circuit board (PCB) and bonding wires or bumps are used to electrically connect the semiconductor chip to the printed circuit board. With the development of electronic industry, various studies have been conducted to improve reliability of semiconductor packages.

### SUMMARY

One or more embodiments provide a semiconductor package with improved electrical properties and increased reliability.

According to one or more embodiments, a semiconductor package may include: a connection substrate; a first processor chip above the connection substrate; a second processor chip above the connection substrate; a memory chip stack structure above the first processor chip; and a bridge structure above the first processor chip and the second processor chip. The bridge structure may electrically connect the first processor chip and the second processor chip. The first processor chip may include a first through via that overlaps the memory chip stack structure.

According to one or more embodiments, a semiconductor package may comprise: a connection substrate; a first processor chip above the connection substrate; a second processor chip above the connection substrate; a first memory chip stack structure above the first processor chip; and a bridge structure above the first processor chip and the second processor chip. The bridge structure may electrically connect the first processor chip and the second processor chip to each other. The first memory chip stack structure may include a plurality of memory chips that are vertically stacked. A top surface of the bridge structure may be coplanar with a top surface of a top memory chip at an uppermost position among the memory chips.

According to one or more embodiments, a semiconductor package may comprise: a connection substrate; a first processor chip above the connection substrate; a second processor chip above the connection substrate; a memory chip above the first processor chip; and a first bridge structure above the first processor chip and the second processor chip. Each of the first and second processor chips may include: a processor lower pad; a first substrate on the processor lower pad; a first through via that penetrates the first substrate; a first wiring structure on the first substrate; and a first processor upper pad and a second processor upper pad on the first wiring structure. The memory chip may include: a memory lower pad that overlaps the first processor upper pad; a second wiring structure on the memory lower pad; a second substrate on the second wiring structure; and a second through via that penetrates the second substrate. The first bridge structure may include: a bridge lower pad that overlaps the second processor upper pad; a third wiring structure on the bridge lower pad; and a third substrate on the third wiring structure. The first through via may overlap the second through via.

### BRIEF DESCRIPTION OF DRAWINGS

FIG. 1A illustrates a cross-sectional view showing a semiconductor package according to one or more embodiments.

FIG. 1B illustrates an enlarged view showing section E1 of FIG. 1A.

FIG. 2 illustrates a cross-sectional view showing a semiconductor package according to one or more embodiments.

FIG. 3 illustrates a cross-sectional view showing a semiconductor package according to one or more embodiments.

FIG. 4 illustrates a cross-sectional view showing a semiconductor package according to one or more embodiments.

FIG. 5 illustrates a simplified plan view showing a semiconductor package according to one or more embodiments.

FIG. 6 illustrates a simplified plan view showing a semiconductor package according to one or more embodiments.

FIG. 7 illustrates a simplified plan view showing a semiconductor package according to one or more embodiments.

### DETAILED DESCRIPTION OF EMBODIMENTS

The following will describe in detail a semiconductor package and its fabrication method according to one or more embodiments in conjunction with the accompanying drawings. It will be understood that when an element or layer is referred to as being “over,” “above,” “on,” “below,” “under,” “beneath,” “connected to” or “coupled to” another element or layer, it can be directly over, above, on, below, under, beneath, connected or coupled to the other element or layer or intervening elements or layers may be present. In contrast, when an element is referred to as being “directly over,” “directly above,” “directly on,” “directly below,” “directly under,” “directly beneath,” “directly connected to” or “directly coupled to” another element or layer, there are no intervening elements or layers present. As used herein, an expression “at least one of” preceding a list of elements modifies the entire list of the elements and does not modify the individual elements of the list. For example, an expression, “at least one of a, b, and c” should be understood as including only a, only b, only c, both a and b, both a and c, both b and c, or all of a, b, and c.

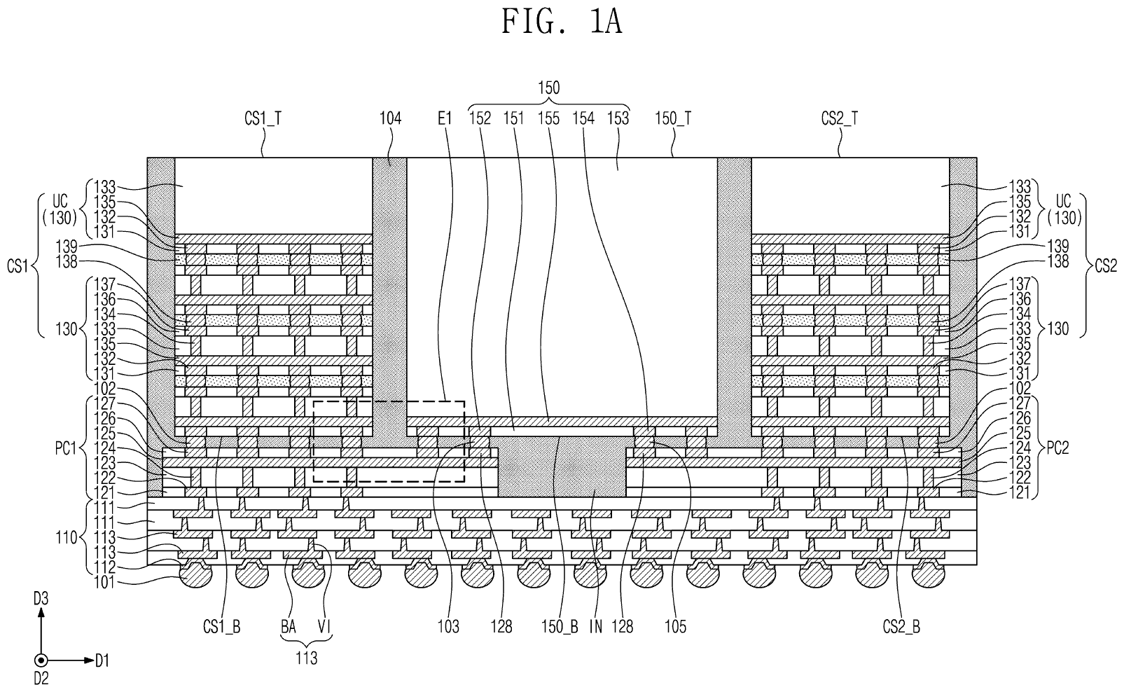

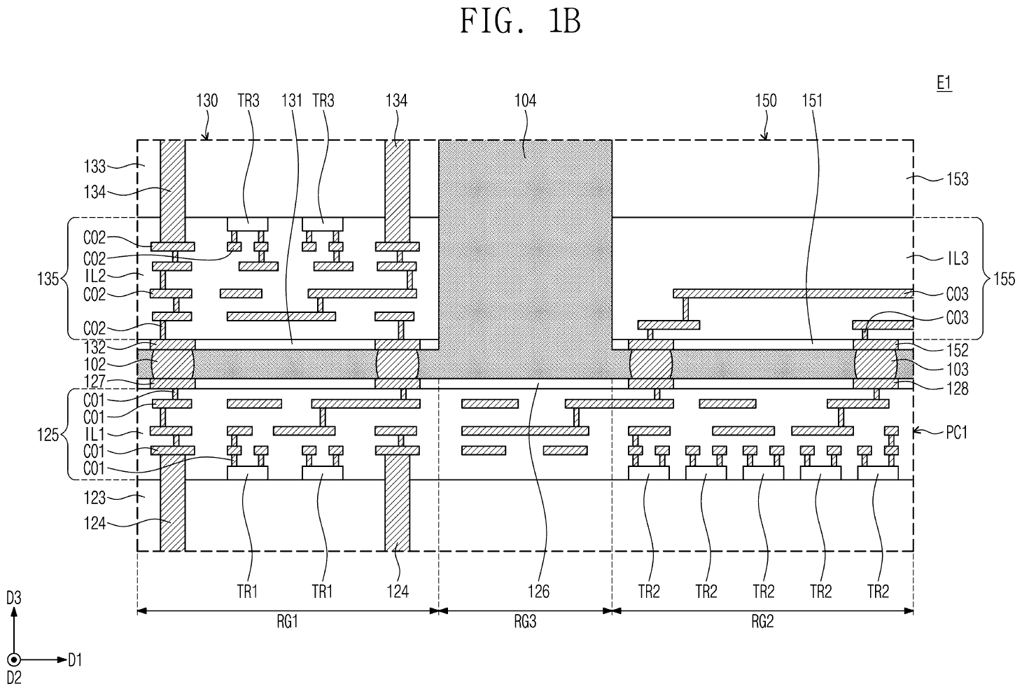

FIG. 1A illustrates a plan view showing a semiconductor package according to one or more embodiments. FIG. 1B illustrates an enlarged view showing section E1 of FIG. 1A.

Referring to FIG. 1A, a semiconductor package may include terminals 101, a connection substrate 110, a molding layer 104, first bumps 102, second bumps 103, third bumps 105, a first processor chip PC1, a second processor chip PC2, a first memory chip stack structure CS1, a second memory chip stack structure CS2, and a bridge structure 150.

The connection substrate 110 may include redistribution patterns 113, photosensitive dielectric layers 111, and bump connection patterns 112. Each of the photosensitive dielectric layers 111 may have a plate shape elongated along a plane that extends in a first direction D1 and a second direction D2. The first direction D1 and the second direction D2 may intersect each other. For example, the first direction D1 and the second direction D2 may be horizontal directions that are orthogonal to each other. The photosensitive dielectric layers 111 may be sequentially stacked along a third direction D3. The third direction D3 may intersect the first direction D1 and the second direction D2. For example, the third direction D3 may be a vertical direction perpendicular to the first direction D1 and the second direction D2.

The photosensitive dielectric layers 111 may include a photo-imageable dielectric (PID) material. The photo-imageable dielectric material may include, for example, at least one of photosensitive polyimide, polybenzoxazole, phenolic polymers, and benzocyclobutene polymers, not being limited thereto.

The redistribution patterns 113 may be surrounded by the photosensitive dielectric layers 111. The redistribution patterns 113 may be disposed in the photosensitive dielectric layers 111. Each of the redistribution patterns 113 may include a base part BA and a via part VI on the base part BA. The base part BA may have a width greater than that of the via part VI. The base part BA may have a linear or bar shape, and the via part VI may have a pillar shape. Although separately described for convenience, the base part BA and the via part VI may be connected without any boundary to form a single unitary object.

The redistribution patterns 113 may include a conductive material. For example, the redistribution patterns 113 may include copper.

The redistribution pattern 113 may have a T shape in which the base part BA is disposed on the via part VI.

The bump connection pattern 112 may be connected to the redistribution pattern 113. The bump connection pattern 112 may be externally exposed from the photosensitive dielectric layer 111. The bump connection pattern 112 may include a conductive material. For example, the bump connection pattern 112 may include copper.

The connection substrate 110 may be an interposer including a semiconductor substrate and vias that penetrate through the semiconductor substrate.

The terminals 101 may be disposed below the connection substrate 110. The terminal 101 may be connected to the bump connection pattern 112. The semiconductor package may be electrically connected through the terminal 101 to an external apparatus. The terminal 101 may include a conductive material.

The first processor chip PC1 and the second processor chip PC2 may be provided on or above the connection substrate 110. Each of the first and second processor chips PC1 and PC2 may include a first lower dielectric layer 121, processor lower pads 122, a first substrate 123, first through vias 124, a first wiring structure 125, a first upper dielectric layer 126, first processor upper pads 127, and second processor upper pads 128.

Each of the first and second processor chips PC1 and PC2 may be or include, for example, a central processing unit (CPU), a graphic processing unit (GPU), or an application processor (AP).

A thickness in the third direction D3 of each of the first and second processor chips PC1 and PC2 may be less than a thickness in the third direction D3 of the connection substrate 110. The thickness in the third direction D3 of each of the first and second processor chips PC1 and PC2 may be about one to two times a thickness in the third direction D3 of a memory chip 130 which will be discussed below. The thickness in the third direction D3 of each of the first and second processor chips PC1 and PC2 may range, for example, from about 50 μm to about 100 μm.

The first processor chip PC1 and the second processor chip PC2 may be located at the same level. The first processor chip PC1 and the second processor chip PC2 may be spaced apart from each other in the first direction D1. The molding layer 104 may include an intervening part IN interposed between the first processor chip PC1 and the second processor chip PC2. A bottom surface of the first processor chip PC1 and a bottom surface of the second processor chip PC2 may be in contact with a top surface of the connection substrate 110. A bottom surface of the first lower dielectric layer 121 may be in contact with a top surface of the photosensitive dielectric layer 111. A bottom surface of the processor lower pad 122 may be in contact with a top surface of the via part VI of the redistribution pattern 113.

The first lower dielectric layer 121 may include a dielectric material. The processor lower pads 122 may be surrounded by the first lower dielectric layer 121. The processor lower pads 122 may be provided in the first lower dielectric layer 121. The processor lower pads 122 may include a conductive material.

The first substrate 123 may be provided on the first lower dielectric layer 121 and the processor lower pads 122. The first substrate 123 may be a semiconductor substrate. In this case, the first substrate 123 may include, for example, silicon, germanium, silicon-germanium, gallium-phosphorus, or gallium-arsenic. In one or more other embodiments, the first substrate 123 may be a dielectric substrate, a silicon-on-insulator (SOI) substrate, or a germanium-on-insulator (GOI) substrate.

The first through via 124 may be connected to the processor lower pad 122 and the first wiring structure 125. The first through via 124 may penetrate in the third direction D3 through the first substrate 123 to electrically connect the processor lower pad 122 to the first wiring structure 125. The first through via 124 may include a conductive material.

The first wiring structure 125 may be provided on the first substrate 123. The first wiring structure 125 may be provided thereon with the first upper dielectric layer 126, the first processor upper pads 127, and the second processor upper pads 128. The first upper dielectric layer 126 may include a dielectric material.

The first processor upper pads 127 and the second processor upper pads 128 may be surrounded by the first upper dielectric layer 126. The first processor upper pads 127 and the second processor upper pads 128 may be provided in the first upper dielectric layer 126. The first processor upper pads 127 and the second processor upper pads 128 may be electrically connected to the first wiring structure 125. The first processor upper pads 127 and the second processor upper pads 128 may include a conductive material.

The first processor upper pads 127 may overlap in the third direction D3 with the first memory chip stack structure CS1 or the second memory chip stack structure CS2. The second processor upper pads 128 may overlap in the third direction D3 with the bridge structure 150.

The first memory chip stack structure CS1 may be provided on or above the first processor chip PC1. The second memory chip stack structure CS2 may be provided on or over the second processor chip PC2. The bridge structure 150 may be provided on or above the first and second processor chips PC1 and PC2. The first memory chip stack structure CS1 may overlap in the third direction D3 with the first processor chip PC1. The second memory chip stack structure CS2 may overlap in the third direction D3 with the second processor chip PC2. The bridge structure 150 may overlap in the third direction D3 with the first processor chip PC1 and the second processor chip PC2.

The first and second memory chip stack structures CS1 and CS2 may be spaced apart from each other in the first direction D1. The bridge structure 150 may be disposed between the first memory chip stack structure CS1 and the second memory chip stack structure CS2. The bridge structure 150, the first memory chip stack structure CS1, and the second memory chip stack structure CS2 may be located at the same level. The bridge structure 150 have a top surface 150_T coplanar with a top surface CS1_T of the first memory chip stack structure CS1 and a top surface CS2_T of the second memory chip stack structure CS2. The top surface 150_T of the bridge structure 150 may be located at the same level as that of the top surface CS1_T of the first memory chip stack structure CS1 and that of the top surface CS2_T of the second memory chip stack structure CS2. The bridge structure 150 have a bottom surface 150_B coplanar with a bottom surface CS1_B of the first memory chip stack structure CS1 and a bottom surface CS2_B of the second memory chip stack structure CS2. The bottom surface 150_B of the bridge structure 150 may be located at the same level as that of the bottom surface CS1_B of the first memory chip stack structure CS1 and that of the bottom surface CS2_B of the second memory chip stack structure CS2.

A thickness in the third direction D3 of the bridge structure 150 may be the same as a thickness in the third direction D3 of each of the first and second memory chip stack structures CS1 and CS2. The thickness in the third direction D3 of the bridge structure 150 may range, for example, from about 695 μm to about 745 μm. A value of about 695 μm to about 745 μm may be provided as a distance in the third direction D3 between the bottom surface 150_B and the top surface 150_T of the bridge structure 150.

Each of the first and second memory chip stack structures CS1 and CS2 may have a width smaller than that of each of the first and second processor chips PC1 and PC2. For example, a width in the first direction D1 of each of the first and second memory chip stack structures CS1 and CS2 may be smaller than a width in the first direction D1 of each of the first and second processor chips PC1 and PC2.

Each of the first and second memory chip stack structures CS1 and CS2 may include memory chips 130 that are stacked in the third direction D3. Each of the memory chips 130 may include a second lower dielectric layer 131, memory lower pads 132, a second substrate 133, second through vias 134, a second wiring structure 135, a second upper dielectric layer 136, and memory upper pads 137.

The memory chip 130 may be a volatile memory chip or a nonvolatile memory chip. The volatile memory chip may be, for example, dynamic random access memory (DRAM), static random access memory (SRAM), thyristor random access memory (TRAM), zero capacitor random access memory (ZRAM), or twin transistor random access memory (TTRAM). The nonvolatile memory chip may be, for example, Flash memory, magnetic random access memory (MRAM), spin-transfer torque magnetic random access memory (STT-MRAM), ferroelectric random access memory (FRAM), phase change random access memory (PRAM), resistive random access memory (RRAM), polymer random access memory, or an insulator resistance change memory.

The second lower dielectric layer 131 may include a dielectric material. The memory lower pads 132 may be surrounded by the second lower dielectric layer 131. The memory lower pads 132 may be provided in the second lower dielectric layer 131. The memory lower pads 132 may include a conductive material.

The second wiring structure 135 may be provided on the second lower dielectric layer 131 and the memory lower pads 132. The second substrate 133 may be provided on the second wiring structure 135. The second substrate 133 may be a semiconductor substrate. In one or more other embodiments, the second substrate 133 may be a dielectric substrate, a silicon-on-insulator (SOI) substrate, or a germanium-on-insulator (GOI) substrate.

The second through via 134 may be connected to the memory upper pad 137 and the second wiring structure 135. The second through via 134 may penetrate in the third direction D3 through the second substrate 133 to electrically connect the memory upper pad 137 to the second wiring structure 135. The second through via 134 may include a conductive material.

The second upper dielectric layer 136 and the memory upper pads 137 may be provided on the second substrate 133. The second upper dielectric layer 136 may include a dielectric material.

The memory upper pads 137 may be surrounded by the second upper dielectric layer 136. The memory upper pads 137 may be provided in the second upper dielectric layer 136. The memory upper pads 137 may be electrically connected to the second wiring structure 135. The memory upper pads 137 may include a conductive material.

A top memory chip UC may be defined which is disposed at an uppermost position among the memory chips 130. The top memory chip UC may include the second lower dielectric layer 131, the memory lower pads 132, the second wiring structure 135, and the second substrate 133. The top memory chip UC may not include any of the second through via 134, the second upper dielectric layer 136, and the memory upper pads 137.

Each of the first and second memory chip stack structures CS1 and CS2 may further include memory bumps 138 and glue layers 139. The memory bump 138 may be disposed between the memory chips 130. The memory chips 130 may be electrically connected to each other through the memory bump 138. The memory bump 138 may be in contact with a bottom surface of the memory lower pad 132 and a top surface of the memory upper pad 137. The memory bump 138 may include a conductive material.

The glue layer 139 may be disposed between the memory chips 130. The glue layer 139 may surround the memory bumps 138. The glue layer 139 may be in contact with a bottom surface of the second lower dielectric layer 131 and a top surface of the second upper dielectric layer 136. The glue layer 139 may include an adhesive polymer material. In one or more other embodiments, each of the first and second memory chip stack structures CS1 and CS2 may not include the glue layers 139, and a portion of the molding layer 104 may be provided between the memory chips 130.

First bumps 102 may be provided between the first memory chip stack structure CS1 and the first processor chip PC1 and between the second memory chip stack structure CS2 and the second processor chip PC2. The first memory chip stack structure CS1 may be electrically connected through the first bump 102 to the first processor chip PC1. The second memory chip stack structure CS2 may be electrically connected through the first bump 102 to the second processor chip PC2. The first bump 102 may be in contact with a bottom surface of the memory lower pad 132 and a top surface of the first processor upper pad 127. The first bump 102 may include a conductive material.

The bridge structure 150 may include a third lower dielectric layer 151, first bridge lower pads 152, second bridge lower pads 154, a third substrate 153, and a third wiring structure 155.

The third lower dielectric layer 151 may include a dielectric material. The first bridge lower pads 152 and the second bridge lower pads 154 may be surrounded by the third lower dielectric layer 151. The first bridge lower pads 152 and the second bridge lower pads 154 may be provided in the third lower dielectric layer 151. The first and second bridge lower pads 152 and 154 may include a conductive material.

The first bridge lower pads 152 may overlap in the third direction D3 with the first processor chip PC1. The second bridge lower pads 154 may overlap in the third direction D3 with the second processor chip PC2.

The third wiring structure 155 may be provided on the third lower dielectric layer 151, the first bridge lower pads 152, and the second bridge lower pads 154. The third substrate 153 may be provided on the third wiring structure 155. The third substrate 153 may be a semiconductor substrate. In one or more other embodiments, the third substrate 153 may be a dielectric substrate, a silicon-on-insulator (SOI) substrate, or a germanium-on-insulator (GOI) substrate. A thickness in the third direction D3 of the third substrate 153 may be greater than a thickness in the third direction D3 of each of the first substrate 123 and the second substrate 133.

The top surface 150_T of the bridge structure 150 may be coplanar with a top surface of the top memory chip UC. The third substrate 153 may have a top surface coplanar with that of the second substrate 133 of the top memory chip UC.

Second bumps 103 may be provided between the bridge structure 150 and the first processor chip PC1. The bridge structure 150 may be electrically connected through the second bump 103 to the first processor chip PC1. The second bump 103 may be in contact with a bottom surface of the first bridge lower pad 152 and a top surface of the second processor upper pad 128 of the first processor chip PC1. The second bump 103 may include a conductive material.

Third bumps 105 may be provided between the bridge structure 150 and the second processor chip PC2. The bridge structure 150 may be electrically connected through the third bump 105 to the second processor chip PC2. The third bump 105 may be in contact with a bottom surface of the second bridge lower pad 154 and a top surface of the second processor upper pad 128 of the second processor chip PC2. The third bump 105 may include a conductive material.

The bridge structure 150 may electrically connect the first processor chip PC1 and the second processor chip PC2 to each other. The first processor chip PC1 may be electrically connected to the second processor chip PC2 through the second bump 103, the first bridge lower pad 152, the third wiring structure 155, the second bridge lower pad 154, and the third bump 105.

The first through vias 124 may overlap in the third direction D3 with the first memory chip stack structure CS1 or the second memory chip stack structure CS2. The first through vias 124 may not overlap in the third direction D3 with the bridge structure 150. When viewed in plan defined by the first direction D1 and the second direction D2, the first through vias 124 may be spaced apart from the bridge structure 150. For example, the first through vias 124 may be spaced apart in the first direction D1 from the bridge structure 150. The bridge structure 150 may be disposed between the first through vias 124 of the first processor chip PC1 and the first through vias 124 of the second processor chip PC2.

The processor lower pad 122, the first through via 124, the first processor upper pad 127, the first bump 102, the memory lower pad 132, the second through via 134, and the memory upper pad 137 may overlap each other in the third direction D3.

The second processor upper pad 128 of the first processor chip PC1, the second bump 103, and the first bridge lower pad 152 may overlap each other in the third direction D3. The second processor upper pad 128 of the second processor chip PC2, the third bump 105, and the second bridge lower pad 154 may overlap each other in the third direction D3.

The molding layer 104 may be provided on the connection substrate 110. The molding layer 104 may surround the first and second processor chips PC1 and PC2, the first and second memory chip stack structures CS1 and CS2, and the bridge structure 150. The top surface 150_T of the bridge structure 150, the top surface CS1_T of the first memory chip stack structure CS1, and the top surface CS2_T of the second memory chip stack structure CS2 may be coplanar with a top surface of the molding layer 104. The top surface 150_T of the bridge structure 150, the top surface CS1_T of the first memory chip stack structure CS1, and the top surface CS2_T of the second memory chip stack structure CS2 may be externally exposed from the molding layer 104. The molding layer 104 may include a polymer material.

Referring to FIG. 1B which illustrates an enlarged view of the section E1 of FIG. 1A, the first wiring structure 125 of the first processor chip PC1 may include a first wiring dielectric layer IL1 and first conductive structures CO1. The first wiring dielectric layer IL1 may be provided between the first substrate 123 and the first upper dielectric layer 126. The first wiring dielectric layer IL1 may be in contact with a top surface of the first substrate 123 and a bottom surface of the first upper dielectric layer 126. The first wiring dielectric layer IL1 may include a dielectric material. The first wiring dielectric layer IL1 may be a multiple layer including a plurality of dielectric layers.

The first processor chip PC1 may further include first transistors TR1 and second transistors TR2. The first transistors TR1 and the second transistors TR2 may be provided on the top surface of the first substrate 123. The first wiring dielectric layer IL1 may surround the first transistors TR1 and the second transistors TR2.

The first conductive structures CO1 may be disposed in the first wiring dielectric layer IL1. The first conductive structures CO1 may be surrounded by the first wiring dielectric layer IL1. The first conductive structure CO1 may be electrically connected to at least one of the first transistor TR1, the second transistor TR2, the first through via 124, the first processor upper pad 127, and the second processor upper pad 128. The first processor upper pad 127 may be electrically connected through the first conductive structures CO1 to the first through via 124.

The first conductive structures CO1 may include one or more of conductive contacts, the conductive lines, and conductive pads. The first conductive structures CO1 may include a conductive material.

The first processor chip PC1 may include a first region RG1 that overlaps in the third direction D3 with the memory chip 130 of the first memory chip stack structure CS1, a second region RG2 that overlaps in the third direction D3 with the bridge structure 150, and a third region RG3 between the first region RG1 and the second region RG2. The third region RG3 of the first processor chip PC1 may be disposed between the first memory chip stack structure CS1 and the bridge structure 150.

The first through vias 124 may be disposed in the first region RG1 of the first processor chip PC1. The first transistors TR1 may be disposed in the first region RG1 of the first processor chip PC1. The first processor upper pads 127 may be disposed in the first region RG1 of the first processor chip PC1. The second transistors TR2 may be disposed in the second region RG2 of the first processor chip PC1. The second processor upper pads 128 may be disposed in the second region RG2 of the first processor chip PC1.

The first region RG1 may have a transistor density less than that of the second region RG2. The number of the first transistors TR1 per unit area of the first region RG1 may be smaller than the number of the second transistors TR2 per unit area of the second region RG2. The second transistors TR2 may be disposed denser than the first transistors TR1. An average distance between the second transistors TR2 may be smaller than an average distance between the first transistors TR1.

Similar to the first processor chip PC1, the second processor chip PC2 may include conductive structures, a wiring dielectric layer, a first region, a second region, and a third region.

The second wiring structure 135 of the memory chip 130 may include a second wiring dielectric layer IL2 and second conductive structures CO2. The second wiring dielectric layer IL2 may be provided between the second substrate 133 and the second lower dielectric layer 131. The second wiring dielectric layer IL2 may be in contact with a bottom surface of the second substrate 133 and a top surface of the second lower dielectric layer 131. The second wiring dielectric layer IL2 may include a dielectric material. The second wiring dielectric layer IL2 may be a multiple layer including a plurality of dielectric layers.

The memory chip 130 may further include third transistors TR3. The third transistors TR3 may be provided on the bottom surface of the second substrate 133. The second wiring dielectric layer IL2 may surround the third transistors TR3.

The second conductive structures CO2 may be disposed in the second wiring dielectric layer IL2. The second conductive structures CO2 may be surrounded by the second wiring dielectric layer IL2. The second conductive structure CO2 may be electrically connected to at least one of the third transistor TR3, the second through via 134, and the memory lower pad 132. The memory lower pad 132 may be electrically connected through the second conductive structures CO2 to the second through via 134.

The second conductive structures CO2 may include one or more of conductive contacts, conductive lines, and conductive pads. The second conductive structures CO2 may include a conductive material.

The third wiring structure 155 of the bridge structure 150 may include a third wiring dielectric layer IL3 and third conductive structures CO3. The third wiring dielectric layer IL3 may be provided between the third substrate 153 and the third lower dielectric layer 151. The third wiring dielectric layer IL3 may be in contact with a bottom surface of the third substrate 153 and a top surface of the third lower dielectric layer 151. The third wiring dielectric layer IL3 may include a dielectric material. The third wiring dielectric layer IL3 may be a multiple layer including a plurality of dielectric layers.

The third conductive structures CO3 may be disposed in the third wiring dielectric layer IL3. The third conductive structures CO3 may be surrounded by the third wiring dielectric layer IL3. The third conductive structure CO3 may be electrically connected to at least one of the first bridge lower pad 152 and the second bridge lower pad (see 154 of FIG. 1A). The first and second bridge lower pads 152 and 154 may be electrically connected to each other through the third conductive structures CO3.

The third conductive structures CO3 may include one or more of conductive contacts, conductive lines, and conductive pads. The third conductive structures CO3 may include a conductive material.

In a semiconductor package according to one or more embodiments, as the first processor chip PC1 and the second processor chip PC2 are electrically connected to each other through the bridge structure 150, there may be an improvement in signal transfer speed and bandwidth between the first processor chip PC1 and the second processor chip PC2 and a reduction in size of the semiconductor package.

In a semiconductor package according to the embodiments, as the bridge structure 150 includes the third substrate 153 having a relatively large thickness, the semiconductor package may improve in warpage control and thermal radiation capacity.

In a semiconductor package according to the embodiments, as the processor chips PC1 and PC2 are connected to each other through the bridge structure 150, the processor chips PC1 and PC2 may be vertically connected to the memory chip stack structures CS1 and CS2.

In a semiconductor package according to the embodiments, as no through via of the processor chip PC1 or PC2 is disposed on a region that overlaps the bridge structure 150, there may be an improvement in integration of transistors of the processor chip PC1 or PC2 on the region that overlaps the bridge structure 150.

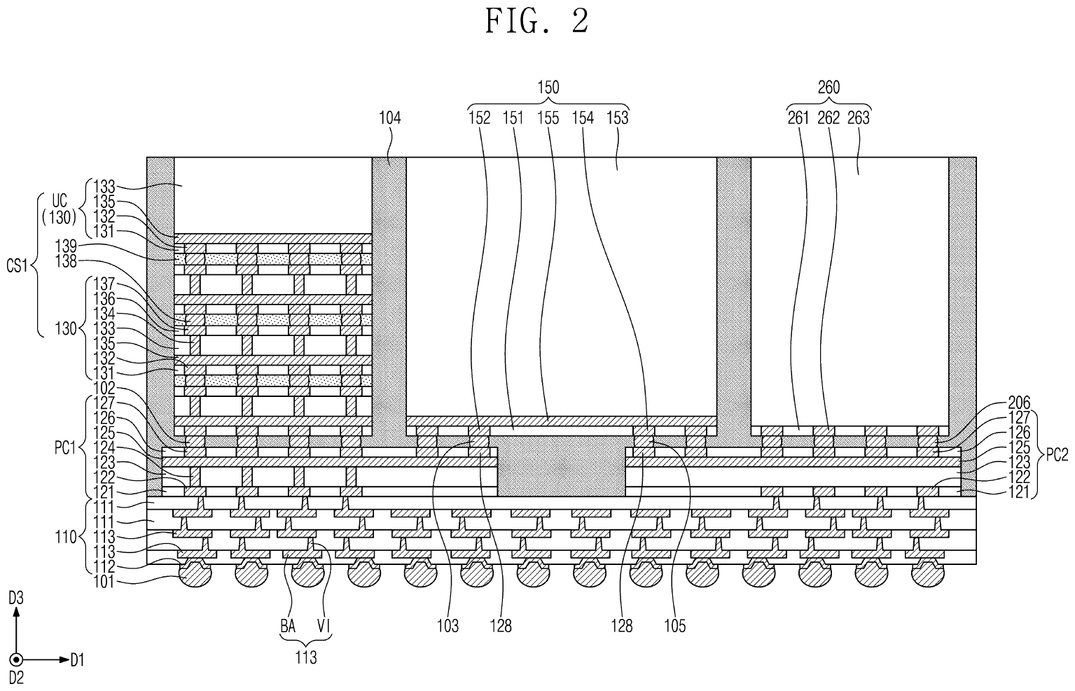

FIG. 2 illustrates a cross-sectional view showing a semiconductor package according to one or more embodiments. A semiconductor package of FIG. 2 may be similar to the semiconductor package of FIGS. 1A and 1B except for the descriptions below.

Referring to FIG. 2, a semiconductor package may include a dummy chip 260 on or above the second processor chip PC2. For example, the second processor chip PC that overlaps in the third direction D3 with the dummy chip 260 may be a graphic processing unit (GPU), and the first processor chip PC1 that overlaps in the third direction D3 with the first memory chip stack structure CS1 may be a central processing unit (CPU).

The bridge structure 150 may be disposed between the dummy chip 260 and the first memory chip stack structure CS1. The bridge structure 150, the first memory chip stack structure CS1, and the dummy chip 260 may be located at the same level. The bridge structure 150, the first memory chip stack structure CS1, and the dummy chip 260 may have their top surfaces that are coplanar with each other. A thickness in the third direction D3 of the dummy chip 260 may be the same as a thickness in the third direction D3 of the bridge structure 150. The dummy chip 260 may have a width smaller than that of each of the first and second processor chips PC1 and PC2. For example, a width in the first direction D1 of the dummy chip 260 may be smaller than a width in the first direction D1 of each of the first and second processor chips PC1 and PC2.

The dummy chip 260 may include a fourth lower dielectric layer 261, dummy lower pads 262, and a fourth substrate 263.

The fourth lower dielectric layer 261 may include a dielectric material. The dummy lower pads 262 may be surrounded by the fourth lower dielectric layer 261. The dummy lower pads 262 may be provided in the fourth lower dielectric layer 261. The dummy lower pads 262 may include a conductive material.

The dummy lower pad 262 may overlap in the third direction D3 with the first processor upper pad 127 of the second processor chip PC2. A fourth bump 206 may further be provided which is in contact with the dummy lower pad 262 and the first processor upper pad 127 of the second processor chip PC2.

The fourth substrate 263 may be provided on the fourth lower dielectric layer 261 and the dummy lower pads 262. The fourth substrate 263 may be a semiconductor substrate. In one or more other embodiments, the fourth substrate 263 may be a dielectric substrate, a silicon-on-insulator (SOI) substrate, or a germanium-on-insulator (GOI) substrate. A thickness in the third direction D3 of the fourth substrate 263 may be greater than a thickness in the third direction D3 of each of the first substrate 123 and the second substrate 133. The fourth substrate 263 may have a top surface coplanar with that of the third substrate 153.

The second processor chip PC2 may not include a through via on a region that overlaps in the third direction D3 with the dummy chip 260. In one or more embodiments, the second processor chip PC2 may not include a through via.

In a semiconductor package according to one or more embodiments, as the dummy chip 260 includes the fourth substrate 263 having a relatively large thickness, the semiconductor package may have an advantage of warpage control and an improvement in thermal radiation capacity.

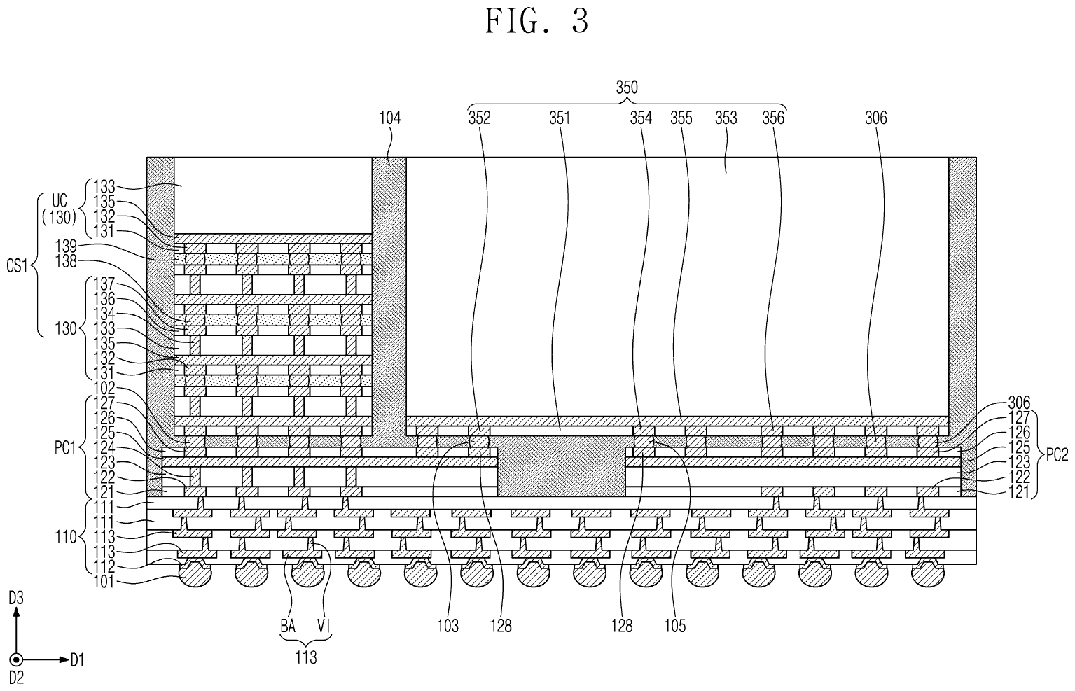

FIG. 3 illustrates a cross-sectional view showing a semiconductor package according to one or more embodiments. A semiconductor package of FIG. 3 may be similar to the semiconductor package of FIGS. 1A and 1B except for the descriptions below.

Referring to FIG. 3, the bridge structure 350 may have a width greater than that of each of the first and second processor chips PC1 and PC2. For example, a width in the first direction D1 of the bridge structure 350 may be greater than a width in the first direction D1 of each of the first and second processor chips PC1 and PC2.

The bridge structure 350 may include a first region that overlaps in the third direction D3 with the first processor chip PC1, a second region that overlaps in the third direction D3 with the second processor chip PC2, and a third region between the first region and the second region. The second region of the bridge structure 350 may have a width greater than that of each of the first and third regions of the bridge structure 350.

The bridge structure 350 may include a third lower dielectric layer 351, first bridge lower pads 352, second bridge lower pads 354, third bridge lower pads 356, a third wiring structure 355, and a third substrate 353.

The third bridge lower pad 356 may overlap in the third direction D3 with the first processor upper pad 127 of the second processor chip PC2. The second bridge lower pad 354 may be disposed between the first and third bridge lower pads 352 and 356.

The semiconductor package may further include a fourth bump 306 in contact with the third bridge lower pad 356 and the first processor upper pad 127 of the second processor chip PC2.

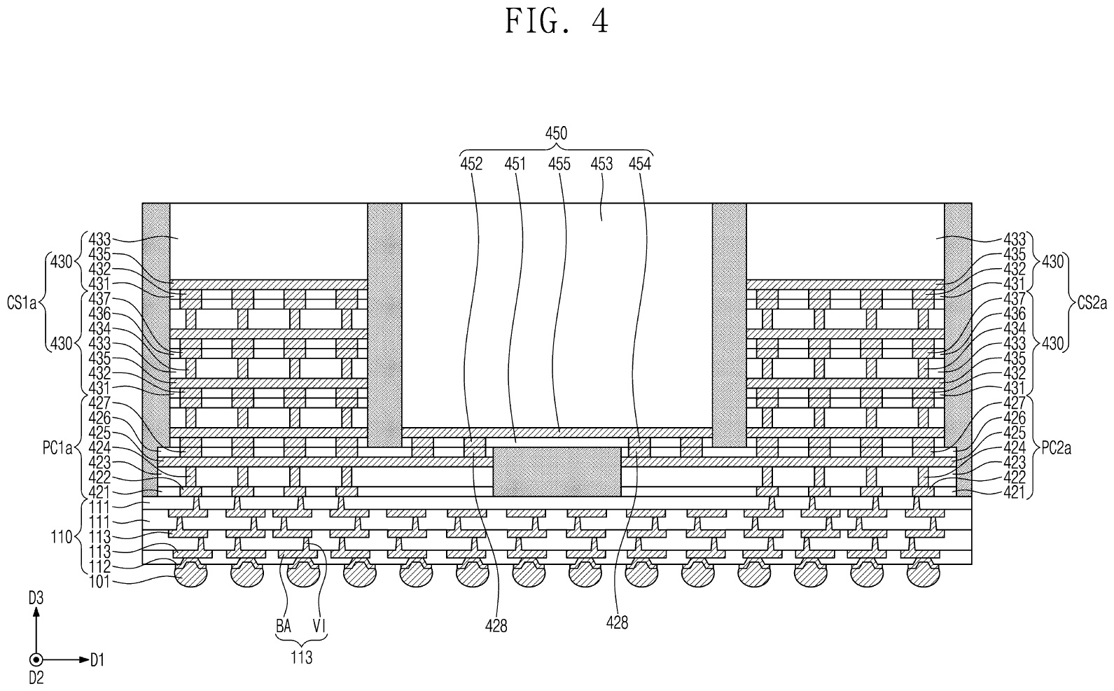

FIG. 4 illustrates a cross-sectional view showing a semiconductor package according to one or more embodiments. A semiconductor package of FIG. 4 may be similar to the semiconductor package of FIGS. 1A and 1B except for the descriptions below.

Referring to FIG. 4, each of first and second processor chips PC1a and PC2a may include a first lower dielectric layer 421, processor lower pads 422, a first substrate 423, first through vias 424, a first wiring structure 425, a first upper dielectric layer 426, first processor upper pads 427, and second processor upper pads 428.

Each of memory chips 430 of first and second memory chip stack structures CS1a and CS2a may include a second lower dielectric layer 431, memory lower pads 432, a second substrate 433, second through vias 434, a second wiring structure 435, a second upper dielectric layer 436, and memory upper pads 437.

A bridge structure 450 may include a third lower dielectric layer 451, first bridge lower pads 452, second bridge lower pads 454, a third wiring structure 455, and a third substrate 453.

A hybrid bonding may be achieved between the first processor chip PC1a and the first memory chip stack structure CS1a. A hybrid bonding may be achieved between the second processor chip PC2a and the second memory chip stack structure CS2a. The first upper dielectric layer 426 may have a top surface in contact with a bottom surface of the second lower dielectric layer 431. The first processor upper pad 427 may have a top surface in contact with a bottom surface of the memory lower pad 432.

A hybrid bonding may be achieved between the memory chips 430. The second upper dielectric layer 436 may have a top surface in contact with the bottom surface of the second lower dielectric layer 431. The memory upper pad 437 may have a top surface in contact with the bottom surface of the memory lower pad 432.

A hybrid bonding may be achieved between the first processor chip PC1a and the bridge structure 450. The second processor upper pad 428 of the first processor chip PC1a may have a top surface in contact with a bottom surface of the first bridge lower pad 452.

A hybrid bonding may be achieved between the second processor chip PC2a and the bridge structure 450. The top surface of the second processor upper pad 428 of the second processor chip PC2a may be in contact with a bottom surface of the second bridge lower pad 454.

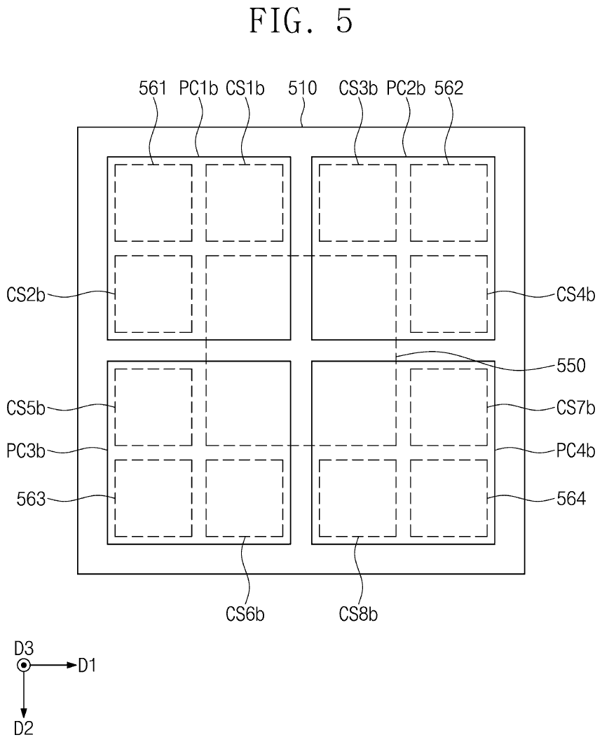

FIG. 5 illustrates a simplified plan view showing a semiconductor package according to one or more embodiments.

Referring to FIG. 5, a semiconductor package may include a first processor chip PC1b, a second processor chip PC2b, a third processor chip PC3b, and a fourth processor chip PC4b on or above a connection substrate 510. For example, the first and fourth processor chips PC1b and PC4b may each be a central processing unit (CPU), and the second and third processor chips PC2b and PC3b may each be a graphic processing unit (GPU).

The first processor chip PC1b may be provided thereon with a first dummy chip 561, a first memory chip stack structure CS1b, and a second memory chip stack structure CS2b. The second processor chip PC2b may be provided thereon with a second dummy chip 562, a third memory chip stack structure CS3b, and a fourth memory chip stack structure CS4b. The third processor chip PC3b may be provided thereon with a third dummy chip 563, a fifth memory chip stack structure CS5b, and a sixth memory chip stack structure CS6b. The fourth processor chip PC4b may be provided thereon with a fourth dummy chip 564, a seventh memory chip stack structure CS7b, and an eighth memory chip stack structure CS8b.

The first and third memory chip stack structures CS1b and CS3b may be disposed between the first and second dummy chips 561 and 562. The second and fifth memory chip stack structures CS2b and CS5b may be disposed between the first and third dummy chips 561 and 563. The sixth and eighth memory chip stack structures CS6b and CS8b may be disposed between the third and fourth dummy chips 563 and 564. The fourth and seventh memory chip stack structures CS4b and CS7b may be disposed between the second and fourth dummy chips 562 and 564.

A bridge structure 550 may overlap in the third direction D3 with the first, second, third, and fourth processor chips PC1b, PC2b, PC3b, and PC4b. The first, second, third, and fourth processor chips PC1b, PC2b, PC3b, and PC4b may be electrically connected to each other through the bridge structure 550.

When viewed in plan as shown in FIG. 5, the bridge structure 550 may be surrounded by the memory chip stack structures CS1b, CS2b, CS3b, CS4b, CS5b, CS6b, CS7b, and CS8b and the dummy chips 561, 562, 563, and 564.

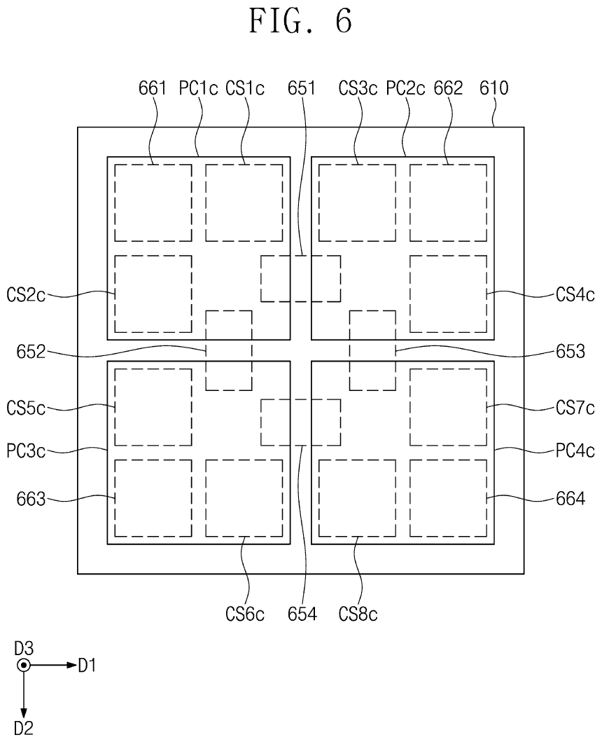

FIG. 6 illustrates a simplified plan view showing a semiconductor package according to one or more embodiments.

Referring to FIG. 6, a semiconductor package may include a first processor chip PC1c, a second processor chip PC2c, a third processor chip PC3c, and a fourth processor chip PC4c on or above a connection substrate 610.

The first processor chip PC1c may be provided thereon with a first dummy chip 661, a first memory chip stack structure CS1c, and a second memory chip stack structure CS2c. The second processor chip PC2c may be provided thereon with a second dummy chip 662, a third memory chip stack structure CS3c, and a fourth memory chip stack structure CS4c. The third processor chip PC3c may be provided thereon with a third dummy chip 663, a fifth memory chip stack structure CS5c, and a sixth memory chip stack structure CS6c. The fourth processor chip PC4c may be provided thereon with a fourth dummy chip 664, a seventh memory chip stack structure CS7c, and an eighth memory chip stack structure CS8c.

There may be provided a first bridge structure 651 that electrically connects the first and second processor chips PC1c and PC2c to each other, a second bridge structure 652 that electrically connects the first and third processor chips PC1c and PC3c to each other, a third bridge structure 653 that electrically connects the second and fourth processor chips PC2c and PC4c to each other, and a fourth bridge structure 654 that electrically connects the third and fourth processor chips PC3c and PC4c to each other.

When viewed in plan as shown in FIG. 6, the first, second, third, and fourth bridge structures 651, 652, 653, and 654 may be surrounded by the memory chip stack structures CS1c, CS2c, CS3c, CS4c, CS5c, CS6c, CS7c, and CS8c and the dummy chips 661, 662, 663, and 664.

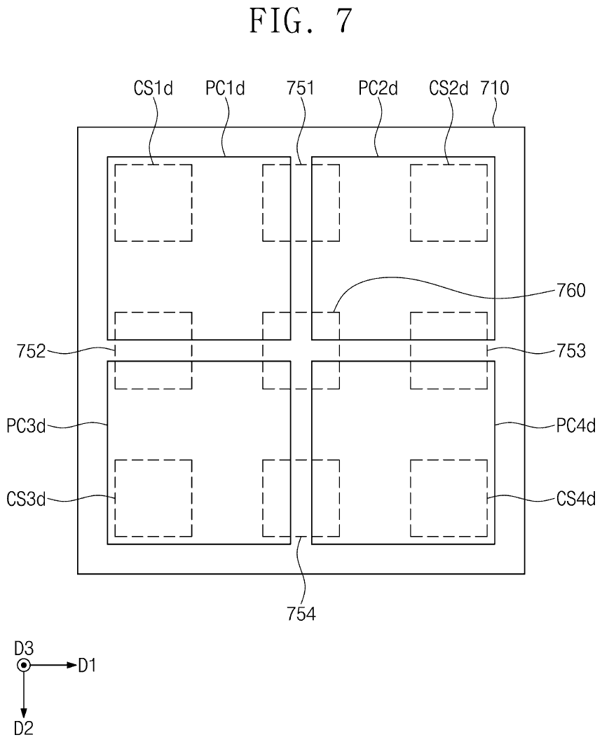

FIG. 7 illustrates a simplified plan view showing a semiconductor package according to one or more embodiments.

Referring to FIG. 7, a semiconductor package may include a first processor chip PC1d, a second processor chip PC2d, a third processor chip PC3d, and a fourth processor chip PC4d on or above a connection substrate 710.

A first memory chip stack structure CS1d may be provided on or above the first processor chip PC1d. A second memory chip stack structure CS2d may be provided on or above the second processor chip PC2d. A third memory chip stack structure CS3d may be provided on or above the third processor chip PC3d. A fourth memory chip stack structure CS4d may be provided on or above the fourth processor chip PC4d.

There may be provided a first bridge structure 751 that electrically connects the first and second processor chips PC1d and PC2d to each other, a second bridge structure 752 that electrically connects the first and third processor chips PC1d and PC3d to each other, a third bridge structure 753 that electrically connects the second and fourth processor chips PC2d and PC4d to each other, and a fourth bridge structure 754 that electrically connects the third and fourth processor chips PC3d and PC4d to each other.

The first bridge structure 751 may be disposed between the first and second memory chip stack structures CS1d and CS2d. The second bridge structure 752 may be disposed between the first and third memory chip stack structures CS1d and CS3d. The third bridge structure 753 may be disposed between the second and fourth memory chip stack structures CS2d and CS4d. The fourth bridge structure 754 may be disposed between the third and fourth memory chip stack structures CS3d and CS3d.

A dummy chip 760 may be provide to overlap in the third direction D3 with the first, second, third, and fourth processor chips PC1d, PC2d, PC3d, and PC4d. When viewed in plan as shown in FIG. 7, the dummy chip 760 may be surrounded by the memory chip stack structures CS1d, CS2d, CS3d, and CS4d and the bridge structures 751, 752, 753, and 754.

A semiconductor package according to the embodiments may include a bridge structure, and thus there may be an improvement in signal transfer speed and bandwidth between processor chips.

A semiconductor package according to the embodiments may include a bridge structure, and thus the semiconductor package may improve in warpage control and increase in thermal radiation capacity.

Although the disclosure has been described in connection with one or more embodiments illustrated in the accompanying drawings, it will be understood by one of ordinary skill in the art that variations in form and detail may be made therein without departing from the spirit and essential feature of the disclosure. The above disclosed embodiments should thus be considered illustrative and not restrictive.

What is claimed is:

1. A semiconductor package, comprising:
a connection substrate;
a first processor chip above the connection substrate;
a second processor chip above the connection substrate;
a memory chip stack structure above the first processor chip; and
a bridge structure above the first processor chip and the second processor chip,
wherein the bridge structure electrically connects the first processor chip and the second processor chip, and
wherein the first processor chip comprises a first through via that overlaps the memory chip stack structure.

2. The semiconductor package of claim 1, wherein the first through via does not overlap the bridge structure.

3. The semiconductor package of claim 1, wherein the first processor chip comprises:
a first region that overlaps the memory chip stack structure;
a second region that overlaps the bridge structure;
a plurality of first transistors in the first region; and
a plurality of second transistors in the second region,
wherein a density of the first transistors on the first region is smaller than a density of the second transistors on the second region.

4. The semiconductor package of claim 1, wherein a top surface of the bridge structure is coplanar with a top surface of the memory chip stack structure.

5. The semiconductor package of claim 1, wherein the memory chip stack structure comprises a plurality of memory chips that are vertically stacked,
wherein each of the memory chips comprises a second through via that overlaps the first through via.

6. The semiconductor package of claim 1, wherein the bridge structure comprises:
a first bridge lower pad electrically connected to the first processor chip;
a second bridge lower pad electrically connected to the second processor chip;
a wiring structure that electrically connects the first bridge lower pad and the second bridge lower pad; and
a substrate on the wiring structure.

7. The semiconductor package of claim 6, wherein the wiring structure includes:
a conductive structure that electrically connects the first bridge lower pad and the second bridge lower pad; and
a wiring dielectric layer that surrounds the conductive structure,
wherein the conductive structure comprises at least one of a conductive contact, a conductive line, and a conductive pad.

8. A semiconductor package, comprising:
a connection substrate;
a first processor chip above the connection substrate;
a second processor chip above the connection substrate;
a first memory chip stack structure above the first processor chip; and
a bridge structure above the first processor chip and the second processor chip,
wherein the bridge structure electrically connects the first processor chip and the second processor chip,
wherein the first memory chip stack structure comprises a plurality of memory chips that are vertically stacked, and
wherein a top surface of the bridge structure is coplanar with a top surface of a top memory chip at an uppermost position among the memory chips.

9. The semiconductor package of claim 8, wherein the top memory chip comprises:
a memory lower pad;
a first wiring structure on the memory lower pad; and
a first substrate on the first wiring structure,
wherein the bridge structure comprises:
a bridge lower pad;
a second wiring structure on the bridge lower pad; and
a second substrate on the second wiring structure, and
wherein a top surface of the first substrate is coplanar with a top surface of the second substrate.

10. The semiconductor package of claim 8, further comprising a dummy chip above the second processor chip,
wherein the bridge structure is between the dummy chip and the first memory chip stack structure.

11. The semiconductor package of claim 10, wherein the dummy chip comprises a dummy lower pad and a substrate on the dummy lower pad.

12. The semiconductor package of claim 10, wherein a top surface of the dummy chip is coplanar with a top surface of the bridge structure.

13. The semiconductor package of claim 8, further comprising a second memory chip stack structure above the second processor chip,
wherein the bridge structure is between the first memory chip stack structure and the second memory chip stack structure.

14. The semiconductor package of claim 8, wherein the first processor chip comprises:
a first substrate;
a first through via that penetrates the first substrate;
a first wiring structure on the first substrate; and
a processor upper pad on the first wiring structure,
wherein one of the memory chips comprises:
a memory lower pad;
a second wiring structure on the memory lower pad;
a second substrate on the second wiring structure; and
a second through via that penetrates the second substrate, and
wherein the first through via, the processor upper pad, the memory lower pad, and the second through via are vertically stacked.

15. The semiconductor package of claim 8, wherein a width of the bridge structure is greater than a width of the first processor chip and a width of the second processor chip.

16. A semiconductor package, comprising:
a connection substrate;
a first processor chip above the connection substrate;
a second processor chip above the connection substrate;
a memory chip above the first processor chip; and
a first bridge structure above the first processor chip and the second processor chip,
wherein each of the first and second processor chips comprises:
a processor lower pad;
a first substrate on the processor lower pad;
a first through via that penetrates the first substrate;
a first wiring structure on the first substrate; and
a first processor upper pad and a second processor upper pad on the first wiring structure,
wherein the memory chip comprises:
a memory lower pad that overlaps the first processor upper pad;
a second wiring structure on the memory lower pad;
a second substrate on the second wiring structure; and
a second through via that penetrates the second substrate,
wherein the first bridge structure comprises:
a bridge lower pad that overlaps the second processor upper pad;
a third wiring structure on the bridge lower pad; and
a third substrate on the third wiring structure, and
wherein the first through via overlaps the second through via.

17. The semiconductor package of claim 16, wherein a bottom surface of the first processor chip and a bottom surface of the second processor chip are in contact with a top surface of the connection substrate.

18. The semiconductor package of claim 16, wherein the connection substrate comprises a redistribution pattern and a dielectric layer on the redistribution pattern,
wherein the redistribution pattern comprises a base part and a via part whose width is smaller than a width of the base part.

19. The semiconductor package of claim 16, wherein the first bridge structure further comprises a lower dielectric layer that surrounds the bridge lower pad,
wherein each of the first and second processor chips further comprises an upper dielectric layer that surrounds the first and second processor upper pads,
wherein the lower dielectric layer is in contact with the upper dielectric layer, and
wherein the bridge lower pad is in contact with the second processor upper pad.

20. The semiconductor package of claim 16, further comprising:
a third processor chip and a fourth processor chip above the connection substrate;
a second bridge structure that electrically connects the second and third processor chips;
a third bridge structure that electrically connects the third and fourth processor chips; and
a fourth bridge structure that electrically connects the first and fourth processor chips.
